(19) United States
(12) Patent Application Publication
(10) Pub. No.: US 2025/0392227 A1
(43) Pub. Date: Dec. 25, 2025

(54) BIDIRECTIONAL SWITCHING ASSEMBLY

(71) Applicant: Rolls-Royce Deutschland Ltd & Co KG, Blankenfelde-Mahlow (DE)

(72) Inventors: Chandana J. GAJANAYAKE, Singapore (SG); Mohamed Sathik MOHAMED HALICK, Singapore (SG); Muneer VALAPPIL, Singapore (SG)

(21) Appl. No.: 19/233,413

(22) Filed: Jun. 10, 2025

(30) Foreign Application Priority Data
Jun. 20, 2024 (GB) 2408848.6

(51) Int. Cl. H02M 5/293; H02M 7/217

(52) U.S. Cl. CPC H02M 5/2932; H02M 7/217

(57) ABSTRACT

A bidirectional switching assembly includes a first switching unit having a first low voltage MOSFET that includes a first gate, a second switching unit having a second low voltage MOSFET that includes a second gate, and a third switching unit having a normally ON high voltage semiconductor switch that includes a third gate connected through high-voltage diodes with an input side and an output side of the switching assembly. The switching units are arranged in series with the third switching unit sandwiched between the first and second switching units. In one direction, the second and third switching units form a cascode. In the other direction, the first and third switching units form a cascode. The switching assembly is configured to conduct a current in either direction when the third switching unit is switched on and block a current in either direction when the third switching unit is switched off.

The present patent document claims the benefit of United Kingdom Patent Application No. GB 2408848.6, filed Jun. 20, 2024, which is hereby incorporated by reference in its entirety.

### TECHNICAL FIELD

The present disclosure relates a bidirectional switching assembly that may be implemented in power systems for aircrafts or other vehicles.

### BACKGROUND

With increased penetration of electrical systems and the progression towards full electric and hybrid propulsion systems, the use of energy storage systems and direct current (DC) power distribution has gained increased use. Multiple loads and sources may be connected to a DC distribution system such as a hybrid propulsion system. In such systems, power converters such as inverters, rectifiers, and DC/DC converters are needed for interfacing electrical propulsion motors, turbo generators, fuel cells, and battery energy storage systems. Further, in such systems, adequate DC protection devices are required. Due to the fact that SSPCs (Solid State Power Controllers, also referred to a Solid State Circuit Breakers) show a fast response time, eliminate arcing during turn-off, and have a high reliability, SSPCs are preferred over electro-mechanical switches.

SSPCs may be implemented using bidirectional switching units that allow a bidirectional control of the current flow between a power source and a load. Bidirectional switching units are conventionally formed by two MOSFET or IGBT devices in common source/collector or common drain/emitter configuration. While allowing bidirectional conducting and blocking, such bidirectional switching units are associated with the disadvantages of high voltage drop, high power loss, and large footprint requirements.

There is a need to provide a bidirectional switching assembly that may be implemented in an effective manner with low power losses and/or be used in other power components such as power converters and battery chargers, or at least provide a useful alternative to known bidirectional switching assemblies. It is also useful to provide power electronics devices in which such bidirectional switching assemblies may be implemented efficiently.

### SUMMARY

According to an aspect of the disclosure, a bidirectional switching assembly is provided. The bidirectional switching unit includes a first switching unit, a second switching unit and a third switching unit. The first switching unit includes a first low voltage MOSFET, wherein the first low voltage MOSFET includes a first gate. The second switching unit includes a second low voltage MOSFET, wherein the second low voltage MOSFET includes a second gate. The third switching unit includes a normally ON high voltage semiconductor switch (such as a JFET or HEMT), wherein the normally ON high voltage semiconductor switch includes a third gate, and wherein the third gate is connected through high-voltage diodes with an input side and with an output side of the switching assembly.

The first switching unit, the third switching unit, and the second switching unit are arranged in series, with the third switching unit sandwiched or positioned between the first switching unit and the second switching unit. In one direction, the third switching unit and the second switching unit form a cascode, and in the other direction, the third switching unit and the first switching unit form a cascode. The switching assembly is configured to conduct a current in either direction when the third switching unit is switched on and is configured to block a current in either direction when the third switching unit is switched off, wherein the third switching unit is switched on and off by switching on and off at least one of the first and second switching units.

Aspects of the disclosure are thus based on the idea to provide for a bidirectional switching assembly that includes one normally ON high-voltage switch only, wherein the high-voltage switch is sandwiched between two low-voltage MOSFET switches of the first and second switching units. The normally ON high-voltage switch has a bidirectional high-voltage blocking capability. The switching status of the MOSFET switches determines through the high-voltage diodes whether the normally ON high-voltage switch is switched off or on, thereby blocking or not blocking the bidirectional switching assembly. This allows the bidirectional switching assembly to be controlled through the MOSFET switches of the first and second switching unit.

Aspects of the disclosure provide for a bidirectional conducting and bidirectional blocking capable switching assembly with smaller footprint, lower loss, lower weight, and higher efficiency. Compared to two high voltage MOSFETs, normally ON high-voltage switches such as JFETs have lower ON state resistance and lower thermal impedance. Normally ON high-voltage switches may dissipate larger power losses without reaching a maximum junction temperature.

A further advantage associated with the present disclosure lies in that low voltage MOSFETs are cheap such that the combination of two MOSFET and one normally ON high-voltage switch is highly competitive in terms of costs and material use. These qualities may help the spreading of SSPC applications and of other applications that require bidirectional switching such as in electro vehicle charging circuits, matrix converter, T type converters, and multiple other power converters that require/use bidirectional switches.

The proposed switching topology may have a normally OFF status when there are no gate signals applied to the MOSFETs, wherein positive or negative high voltages applied across the switching assembly are blocked by the normally ON high-voltage switch. When the MOSFETs are switched ON by applying corresponding gate signals, the switching assembly conducts current in both directions.

The switching assembly is bidirectional, which means that the switching assembly allows to control the current flow through the switching assembly in two directions. More particularly, the switching assembly is a four-quadrant switch as it may conduct current in both directions and block voltage in both directions.

According to some embodiments, the high-voltage diodes include a first high-voltage diode connected at one terminal to the gate of the normally ON high voltage semiconductor switch and connected at the other terminal to the input side of the first switching unit. The high-voltage diodes further include a second high-voltage diode connected at one terminal to the gate of the normally ON high voltage semiconductor switch and connected at the output side of the second switching unit. The first and second high-voltage diodes serve to block the gate of the normally ON high voltage semiconductor switch from the high voltage present at the input and the output of the switching assembly. They are not carrying large currents and are only used for blocking voltage.

In this respect, the bidirectional switching assembly is suitable for conducting and blocking high voltages, e.g., at least 100V or at least 1000 V.

In some embodiments, the first switching unit and the second switching unit each include an antiparallel diode arranged antiparallel to the first low voltage MOSFET and the second low voltage MOSFET, respectively. Accordingly, each of the first and second switching units includes an antiparallel diode. Such an antiparallel diode allows to pass current through the switching unit when the MOSFET of the switching unit is blocking. For example, when the third switching unit and the second switching unit are switched on to conduct a current in one direction, the first switching unit may be switched off. In such case, the antiparallel diode makes sure that the current flowing through the third switching unit and the second switching unit also passes through the first switching unit to allow a current path through the switching assembly. In other embodiments, the MOSFET of the first switching unit is also switched on in such case.

In some embodiments, the first switching unit and the second switching unit additionally each include a bidirectional transient voltage suppressor (TVS) diode arranged in parallel to the first low voltage MOSFET and the second low voltage MOSFET, respectively. A TVS diode serves as protection from transient voltage spikes.

In some embodiments, the first low voltage MOSFET and the second low voltage MOSFET are controlled with the same logic signal. Accordingly, they are switched on and off simultaneously in such embodiment. Alternatively, the first low-voltage MOSFET and the second low-voltage MOSFET are controlled by independent logical signals. In either embodiment, control of the MOSFETs may be provided by a controller that controls a gate driver of the MOSFETs, wherein such controller may be integrated into the gate driver or be a separate controlling unit.

In some embodiments, the first low voltage MOSFET and the second low voltage MOSFET are driven by independent (and isolated) gate drivers, wherein the independent gate drivers may provide the same or different logical signals to the gate of the respective MOSFET. Providing independent gate drivers is associated with the advantage that the first and second low-voltage MOSFETs may be controlled independently. Also, the independent gate drivers may be powered independently. In other embodiments, the first low-voltage MOSFET and the second low-voltage MOSFET are controlled by the same gate driver.

In a further embodiment, the switching assembly is configured to conduct a current in the one direction when at least the third switching unit and the second switching unit are switched on and is further configured to conduct a current in the other direction when at least the third switching unit and the first switching unit are switched on. This is associated with the feature that in one direction the third switching unit and the second switching unit form a cascode and in the other direction the third switching unit and the first switching unit form a cascode. In this respect, a cascode within the meaning of the present disclosure is any sequence of semiconductor switches in which the source/drain output of one semiconductor switch is connected to the source/drain input of the other semiconductor switch.

In some embodiments, the first low voltage MOSFET and a second low voltage MOSFET are in OFF state when there are no gate signals applied by the first and second gate drivers. Accordingly, in such case, an ON signal has a to be applied to the gates by the respective gate drivers for the MOSFETs to become conductive. When the MOSFETs are in the OFF state, the normally ON high-voltage switch is also switched off, thereby blocking high voltages in both directions.

Both the first low-voltage MOSFET and the second low-voltage MOSFET may include a plurality of low-voltage MOSFETs, which are arranged in parallel. This allows to increase the current capacity and/or to reduce the voltage drop and power loss. In a similar manner, in certain embodiments, the normally ON high-voltage switch includes a plurality of such switches arranged in parallel.

The high-voltage diodes that shield the gate of the normally ON high-voltage switch may include one or several diodes arranged in series. When several diodes are arranged in series, the forward voltage is increased and the reverse blocking capabilities are enhanced.

In a further embodiment, the first low voltage MOSFET and the second low voltage MOSFET are configured to have a maximum drain-to-source voltage of 40 Volts and to have a maximum current through the drain-source channel of 500 Ampere. Further, at the same time, the resistance of the drain-source channel in the ON state may be 0.5 mΩ (milliohm).

On the other hand, in embodiments, the normally ON high-voltage switch may have a maximum drain-to-source voltage of 1200 Volts or 2400 Volts and a maximum current through the drain-source channel of 120 Amperes. Further, at the same time, the resistance of the drain-source channel in the ON state may be 9 mΩ (milliohm).

In a further embodiment, the normally ON high voltage semiconductor switch includes a dual gate configuration with a first third gate and a second third gate, wherein the first third gate is connected through a high-voltage diode with the input side of the switching assembly and the second third gate is connected through a high-voltage diode with the output side of the switching assembly. Such embodiment is based on a semiconductor switch topology in which the semiconductor switch includes two gates, wherein the two gates are used for blocking in both directions. More particularly, each high-voltage diode is connected to one of the dual gates, shielding the respective gate against high voltage. A dual gate configuration increases the blocking capability of the normally ON high-voltage switch in both directions. Also, the circuit complexity of a circuit that implements the bidirectional switching assembly may be reduced and become simpler.

In a still further embodiment, the third semiconductor switch includes first and second normally ON high voltage semiconductor switches arranged in series and both sandwiched between the first and second semiconductor switches, wherein the gates of the first and second normally ON high voltage semiconductor switches are each connected through high-voltage diodes with an input side and with an output side of the switching assembly. This embodiment allows to increase the blocking voltage by connecting two or more of the normally ON high-voltage semiconductor switches in series. Accordingly, a switching assembly with higher voltage levels, i.e., that is robust for higher voltage levels is provided for by connecting several of the normally ON high-voltage switches in series. A scalable bidirectional semiconductor switch is provided for.

In a variant of such embodiment, the assembly further includes a balancing circuit for balancing the voltage across the first and second normally ON high voltage semiconductor switches, wherein the balancing circuit includes two avalanche diodes, which may be connected back to back. Further, the avalanche diodes may connect the gates of the first and second normally ON high voltage semiconductor switches.

Such balancing circuit serves to allow bidirectional conducting and bidirectional blocking of the switching assembly and allows for equal sharing of the blocking voltage between the two normally ON high-voltage switches. The back to back avalanche diodes provide the function that when one of the avalanche diodes is conducting the other one is blocking based on the current directions.

In a further embodiment, the balancing circuit further includes a low-voltage diode having a terminal connected to a point between the first and third semiconductor switches and a terminal connected to the gate of the first normally ON high voltage semiconductor switch, and a low-voltage diode having a terminal connected to a point between the third and second semiconductor switches and a terminal connected to the gate of the second normally ON high voltage semiconductor switch. Further, the balancing circuit may include resistors that are used to set the desired voltages, wherein the resistors are arranged outside of the current conduction path through the switching assembly.

In a further embodiment, the normally ON high voltage semiconductor switch includes a drift region arranged between a source terminal and a drain terminal of the semiconductor switch, wherein the gate terminal is arranged in the middle of the drift region, at even space to the source terminal and the drain terminal. The background of this embodiment lies in that conventional normally ON high voltage semiconductor switches such as a JFETs struggle to fully block voltage in both directions, e.g., in high-voltage applications. In particular, in high-voltage JFETs, the reverse blocking voltage V_{DS} is lower than the forward blocking voltage V_{SD} due to the proximity of the gate terminal to the source. To address this problem, the embodiment shifts the gate terminal to the middle of the structure.

In a variant of that embodiment, the normally ON high voltage semiconductor switch includes two gate terminals, wherein the first and second gate terminals are arranged symmetrically with respect to the source terminal and the drain terminal.

In embodiments, the normally ON high voltage semiconductor switch is a JFET (“junction field-effect transistor”) or HEMT (“high-electron-mobility transistor”) semiconductor switch. In particular, it may be a SiC JFET or GaN HEMT semiconductor switch. Both are bidirectional switches are able to block or conduct currents in both directions and are ON when there is no gate signal applied.

The use of a bidirectional semiconductor assembly is not limited and may occurs in all circuits that require bidirectional switching. In embodiments, the switching assembly is an element of a solid state power controller, a matrix converter, a T-Type converter, a Vienna rectifier, or a battery charging circuit, wherein these implementations are to be understood as examples only.

Accordingly, in a further aspect, a power system is provided, wherein the power system includes a power bus having a positive voltage rail and a negative voltage rail and configured to connect a power source with a load, and a bidirectional solid state power controller arranged in at least one of the positive voltage rail and the negative voltage rail. The bidirectional solid state power controller includes a bidirectional switching assembly as described herein. This aspect thus implements a bidirectional switching assembly in a solid state power controller.

In some embodiments, the power system further includes a controller, wherein the controller is configured to receive information or determine that there is a fault (somewhere in the system), wherein, in such case, the controller is further configured to control the first and second switching units such that these are switched off. By the first and second switching units being switched off (namely, by the respective MOSFETs being switched off), the normally ON high-voltage switch is switched off as well and blocks a high-voltage on the voltage rail. Thereby, the bidirectional switching assembly blocks the conduction of current on the voltage rail.

In a still further aspect, a matrix converter is provided that implements bidirectional switching assemblies. More particularly, the matrix converter includes an AC input side, an AC output side, and an array of bidirectional switching assemblies as described herein. The array of bidirectional switching assemblies is arranged between the AC input side and the AC output side. A matrix converter may include a plurality of bidirectional power switches that directly connect an AC voltage source to a load. Unlike traditional converters that use a DC link (such as with rectifiers and inverters), a matrix converter achieves power conversion without any intermediate energy storage.

The skilled person will appreciate that except where mutually exclusive, a feature or parameter described in relation to any one of the above aspects may be applied to any other aspect. Furthermore, except where mutually exclusive, any feature or parameter described herein may be applied to any aspect and/or combined with any other feature or parameter described herein.

### BRIEF DESCRIPTION OF THE DISCLOSURE

The disclosure is explained in more detail on the basis of exemplary embodiments with reference to the accompanying drawings.

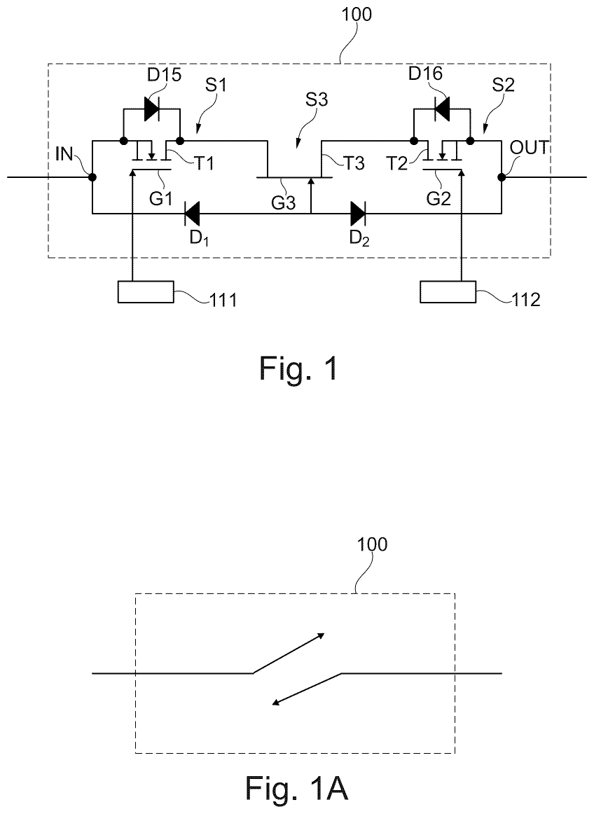

FIG. 1 is an embodiment of a bidirectional switching assembly that includes first and second switching units and a third switching unit sandwiched between the first and second switching units, wherein the first and second switching units each include a low-voltage MOSFET and wherein the third switching unit includes a normally ON high-voltage semiconductor switch that is controlled by the low-voltage MOSFETs.

FIG. 1A is a schematic depiction of the bidirectional switching assembly of FIG. 1.

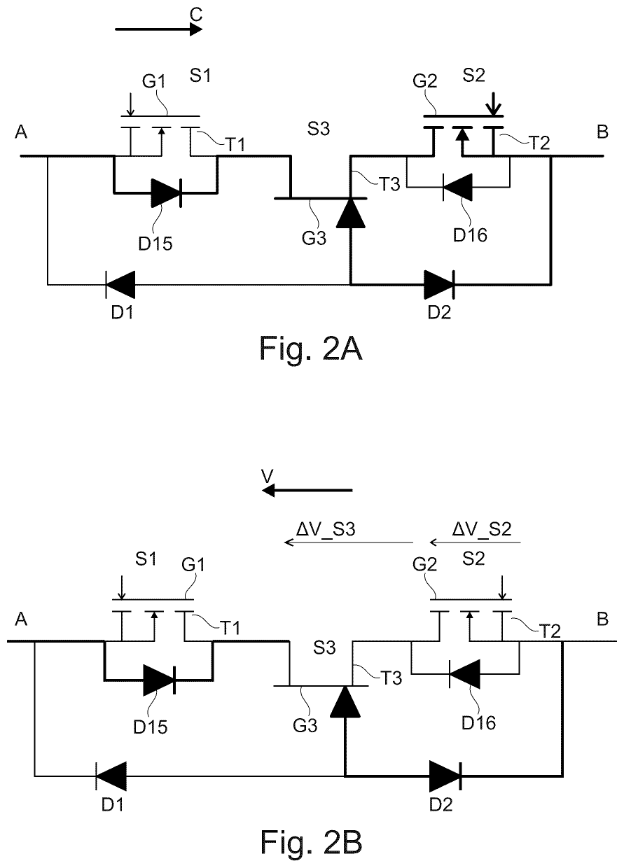

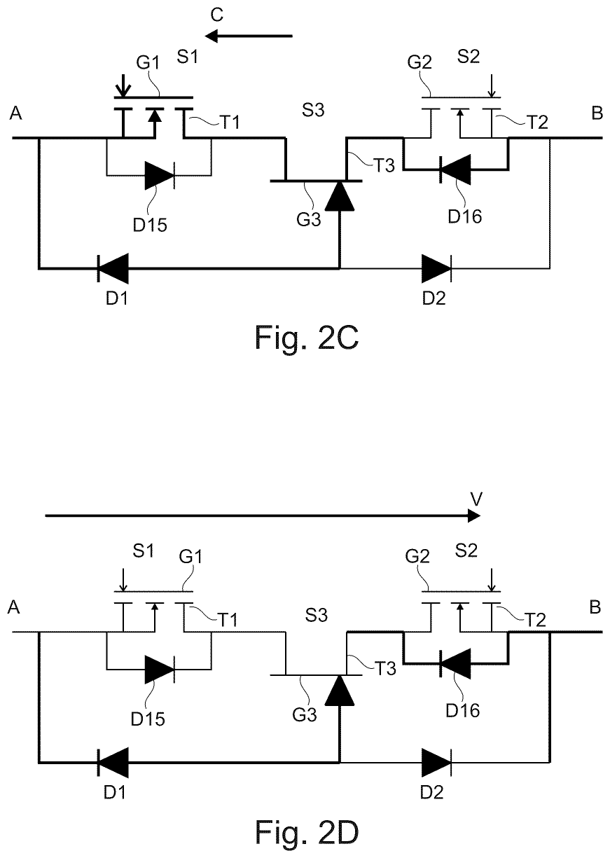

FIG. 2A depicts the bidirectional switching assembly of FIG. 1 when conducting current in a forward direction.

FIG. 2B depicts the bidirectional switching assembly of FIG. 1 when blocking current in a forward direction.

FIG. 2C depicts the bidirectional switching assembly of FIG. 1 when conducting current in a backward direction.

FIG. 2D depicts the bidirectional switching assembly of FIG. 1 when blocking current in a backward direction.

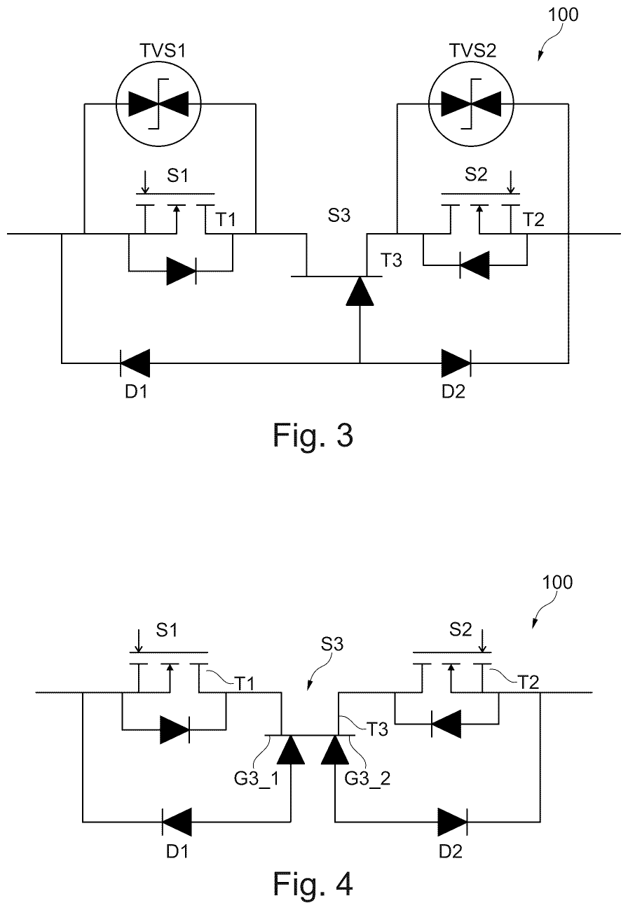

FIG. 3 is a variant of the bidirectional switching assembly of FIG. 1 that additionally includes transient voltage suppressors for over protection.

FIG. 4 is a further variant of the bidirectional switching assembly of FIG. 1 in which the normally ON high-voltage semiconductor switch includes a dual gate configuration.

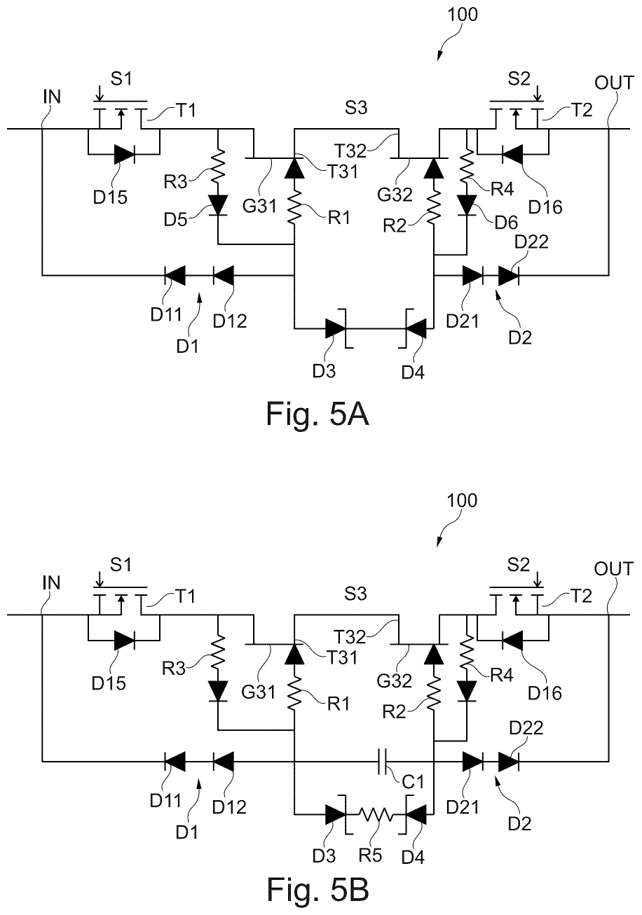

FIG. 5A is a further embodiment of a bidirectional switching assembly that includes first and second switching units and a third switching unit sandwiched between the first and second switching units, wherein the first and second switching units each include a low-voltage MOSFET, and wherein the third switching unit includes first and second normally ON high-voltage semiconductor switches that are connected in series and controlled by the low-voltage MOSFETs.

FIG. 5B is a variant of the bidirectional switching assembly of FIG. 5A in which a slew rate control is additionally integrated.

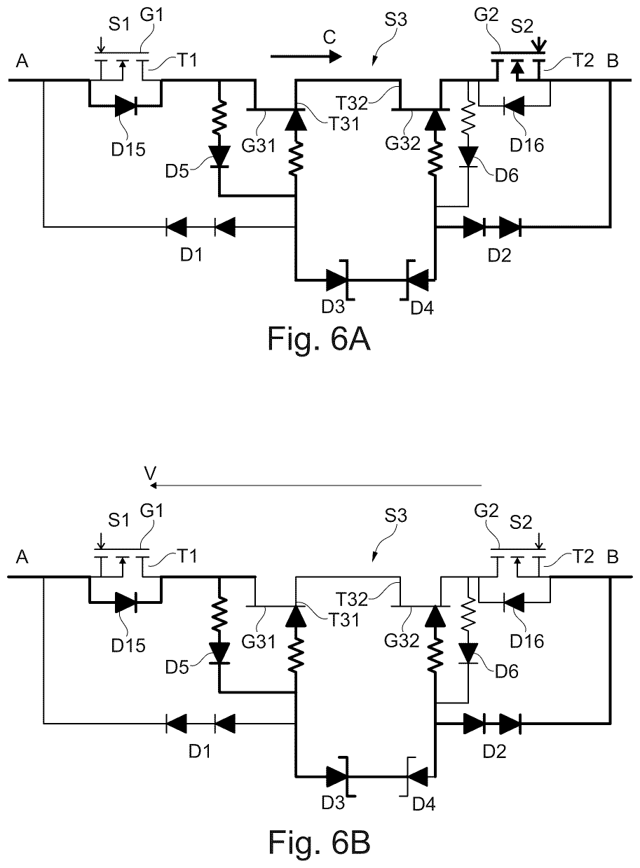

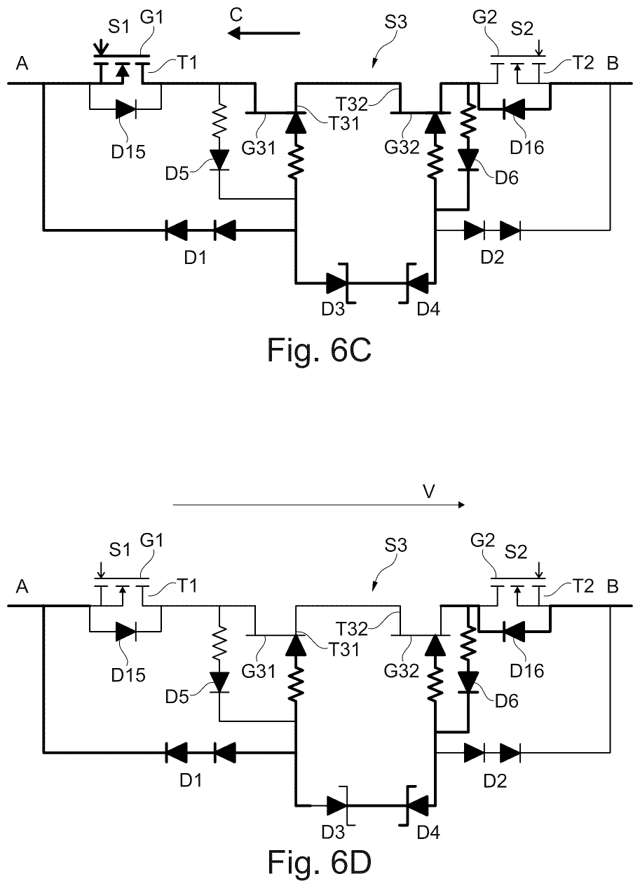

FIG. 6A depicts the bidirectional switching assembly of FIG. 5A when conducting current in a forward direction.

FIG. 6B depicts the bidirectional switching assembly of FIG. 5A when blocking current in a forward direction.

FIG. 6C depicts the bidirectional switching assembly of FIG. 5A when conducting current in a backward direction.

FIG. 6D depicts the bidirectional switching assembly of FIG. 5A when blocking current in a backward direction.

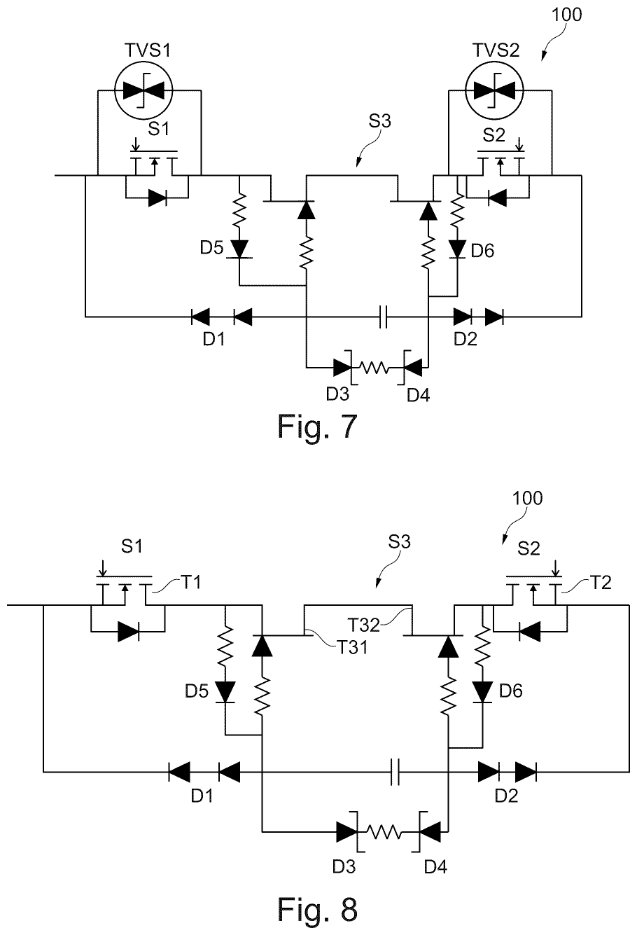

FIG. 7 is a variant of the bidirectional switching assembly of FIG. 5B that additionally includes transient voltage suppressors for over protection.

FIG. 8 is a further variant of the bidirectional switching assembly of FIG. 5B in which a common drain configuration of the normally ON high-voltage semiconductor switches is implemented.

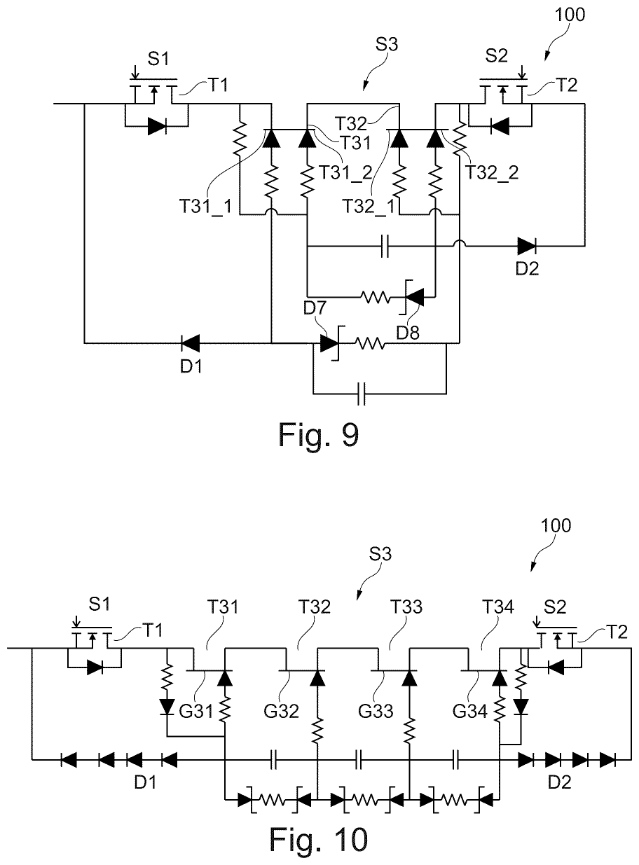

FIG. 9 is a further variant of the bidirectional switching assembly of FIG. 5B in which the first and second normally ON high-voltage semiconductor switches include a dual gate configuration.

FIG. 10 is a further embodiment of a bidirectional switching assembly that includes first and second switching units and a third switching unit sandwiched between the first and second switching units, wherein the first and second switching units each include a low-voltage MOSFET, and wherein the third switching unit includes four normally ON high-voltage semiconductor switches that are connected in series and controlled by the low-voltage MOSFETs.

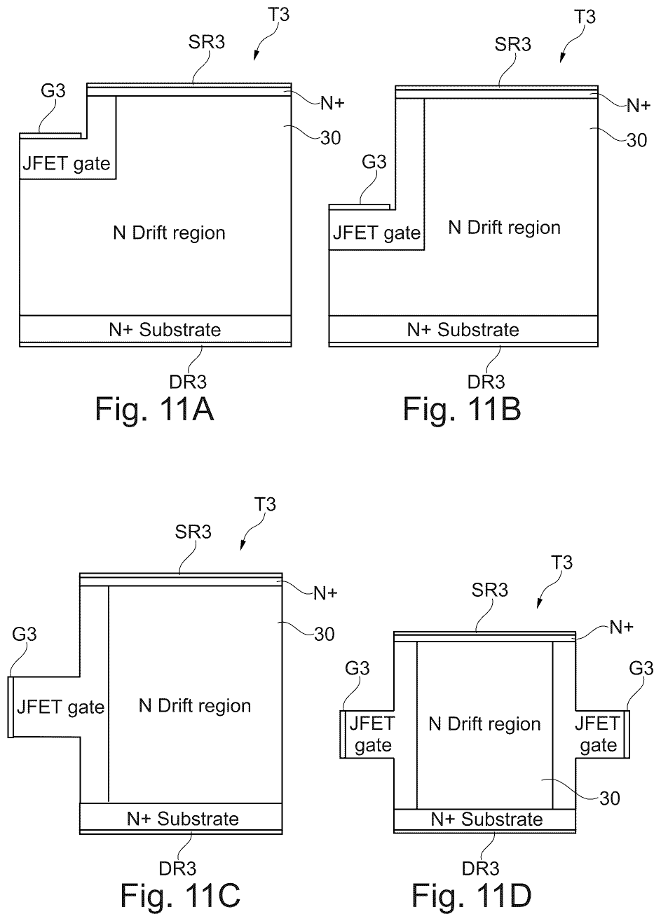

FIGS. 11A-11E show different embodiments of a JFET semiconductor switch with different positions of the JFET gate with respect to the JFET source and the JFET drain.

FIG. 12 is a power system that includes a power bus with a positive voltage rail and a negative voltage and a bidirectional solid state power controller, wherein the bidirectional solid state power controller includes a bidirectional switching assembly in accordance with FIG. 1 in the positive voltage rail.

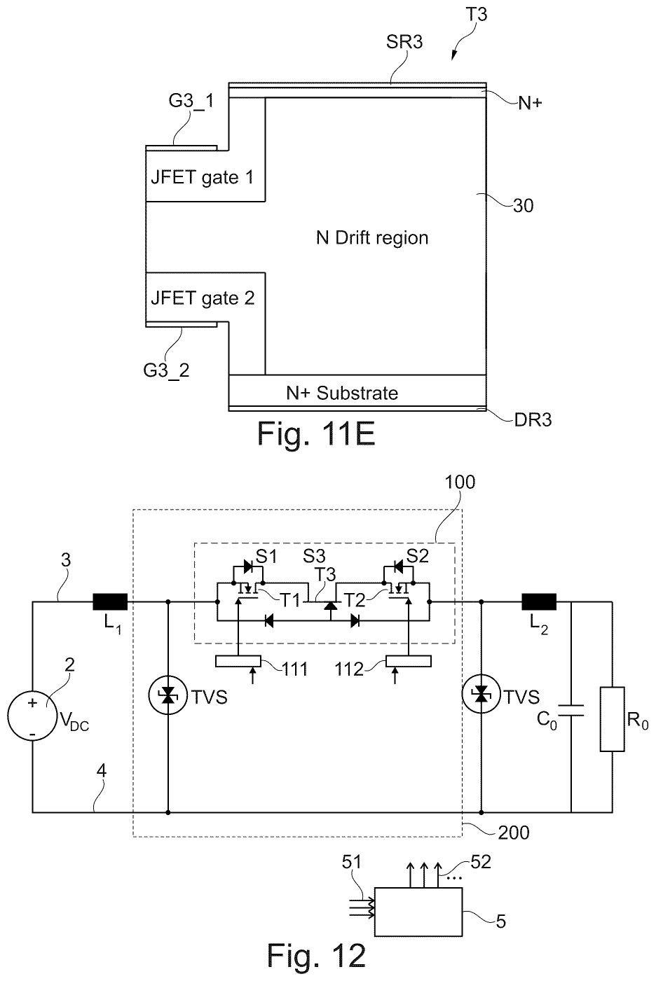

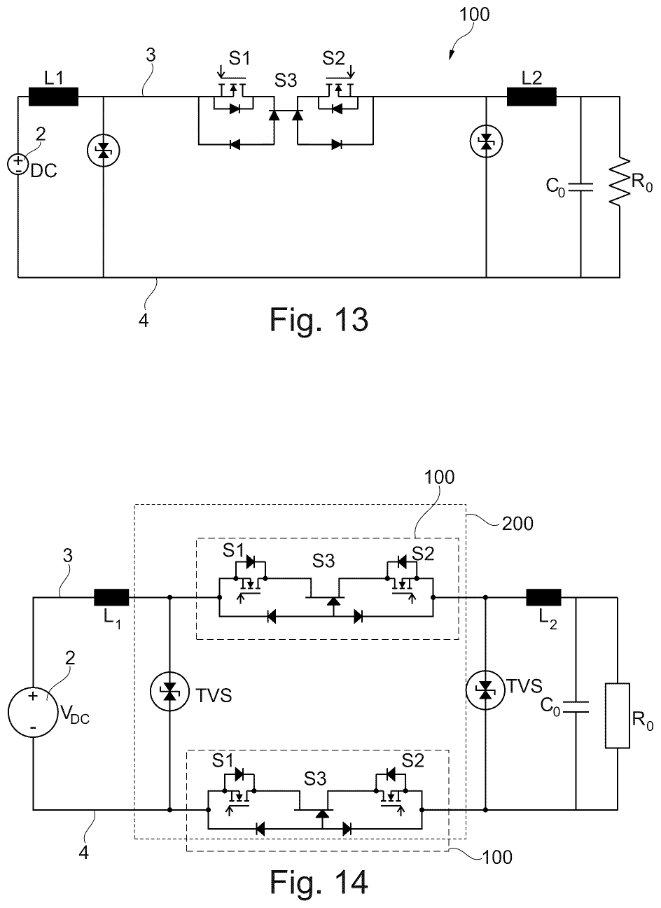

FIG. 13 is a power system similar to the power system of FIG. 12, wherein a bidirectional switching assembly in accordance with FIG. 4 is arranged in the positive voltage rail.

FIG. 14 is a power system similar to the power system of FIG. 12, wherein a bidirectional switching assembly in accordance with FIG. 1 is arranged both in the positive voltage rail and the negative voltage rail.

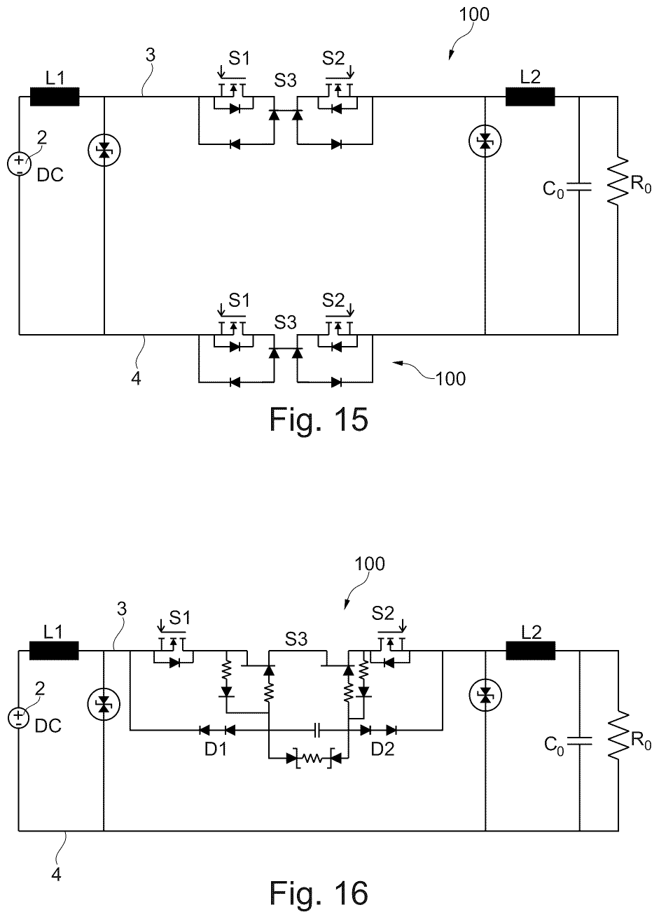

FIG. 15 is a power system similar to the power system of FIG. 12, wherein a bidirectional switching assembly in accordance with FIG. 4 is arranged both in the positive voltage rail and the negative voltage rail.

FIG. 16 is a power system similar to the power system of FIG. 12, wherein a bidirectional switching assembly in accordance with FIG. 5B is arranged in the positive voltage rail.

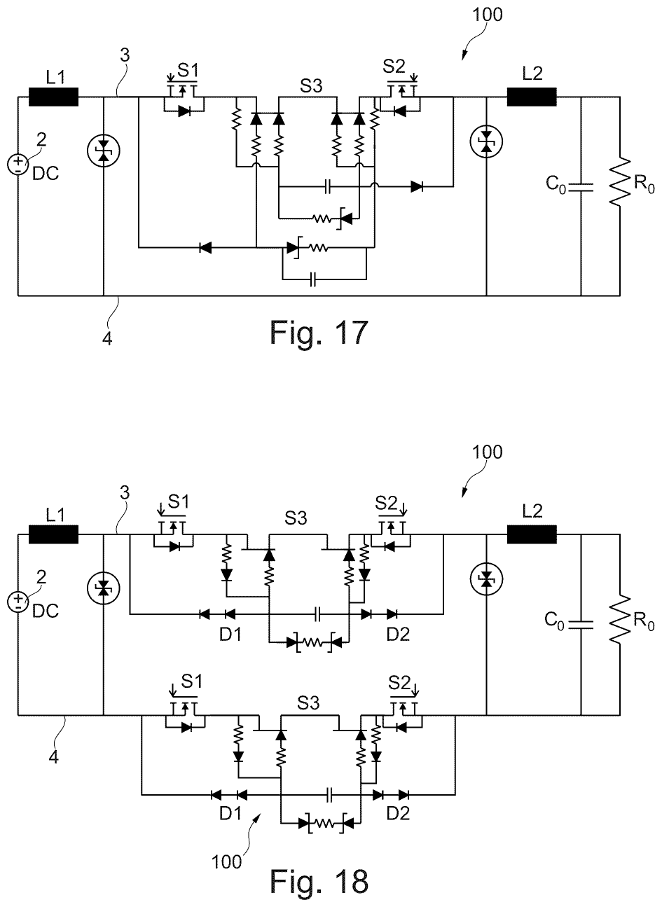

FIG. 17 is a power system similar to the power system of FIG. 12, wherein a bidirectional switching assembly in accordance with FIG. 9 is arranged in the positive voltage rail.

FIG. 18 is a power system similar to the power system of FIG. 12, wherein a bidirectional switching assembly in accordance with FIG. 5B is arranged both in the positive voltage rail and the negative voltage rail.

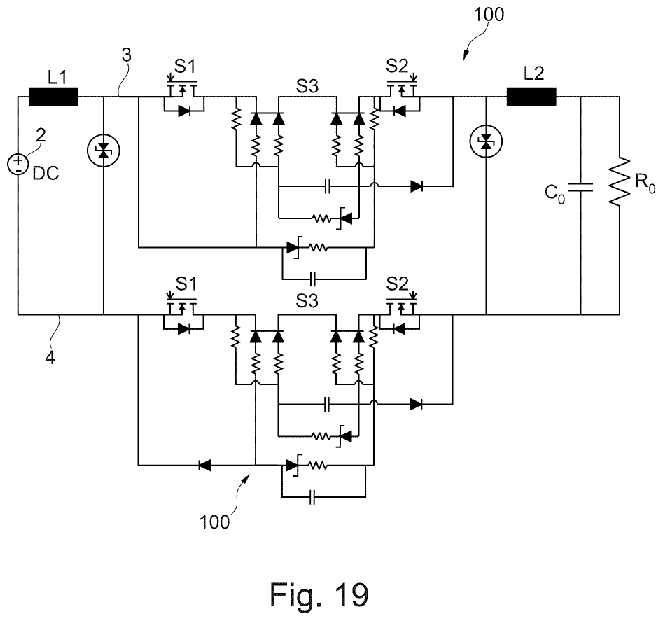

FIG. 19 is a power system similar to the power system of FIG. 12, wherein a bidirectional switching assembly in accordance with FIG. 9 is arranged both in the positive voltage rail and the negative voltage rail.

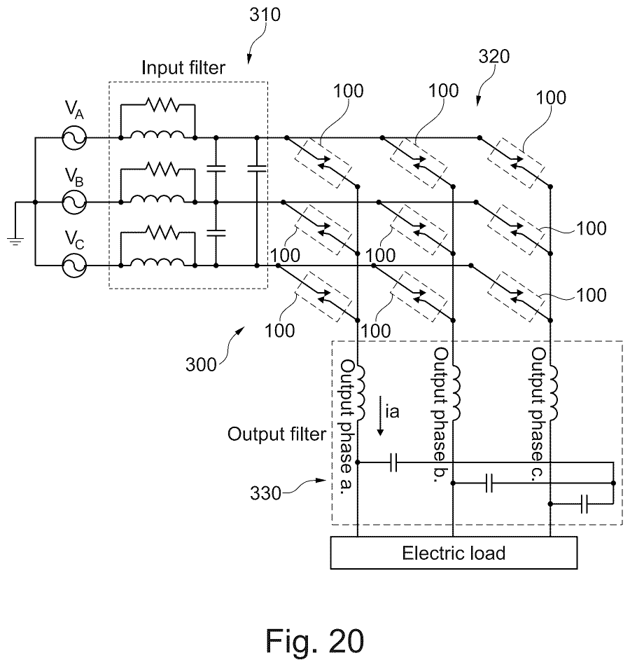

FIG. 20 is an embodiment of a matrix converter that implements bidirectional switching assemblies.

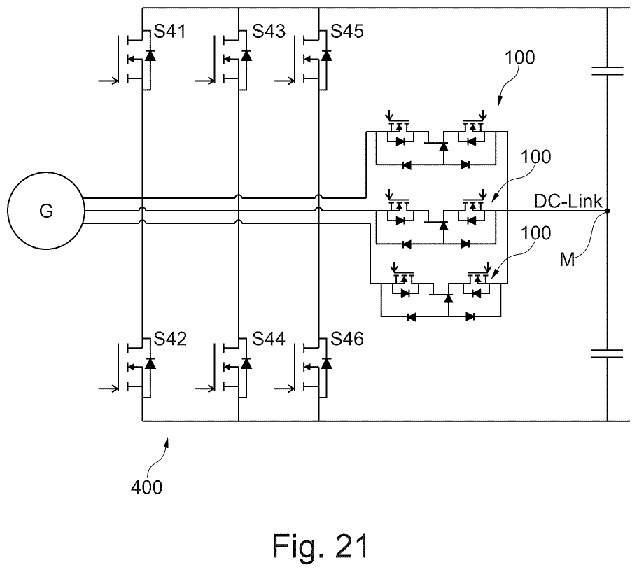

FIG. 21 is an embodiment of a T-type converter that implements bidirectional switching assemblies.

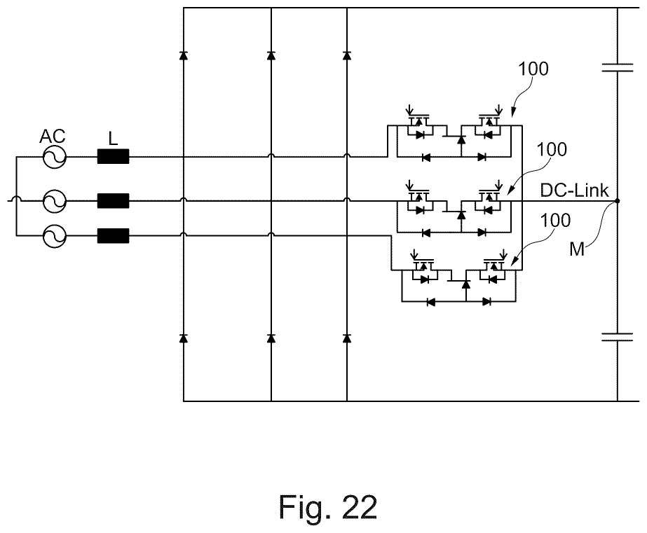

FIG. 22 is an embodiment of a Vienna rectifier that implements bidirectional switching assemblies.

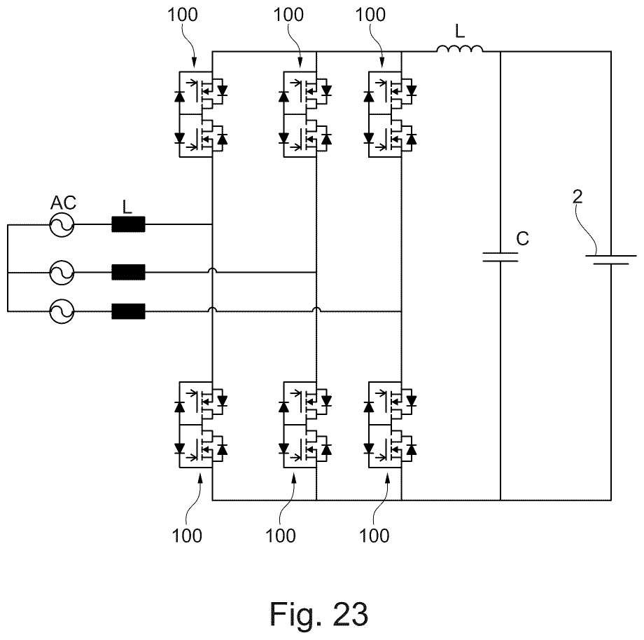

FIG. 23 is an embodiment of a three phase single stage charging topology with a battery that implements bidirectional switching assemblies.

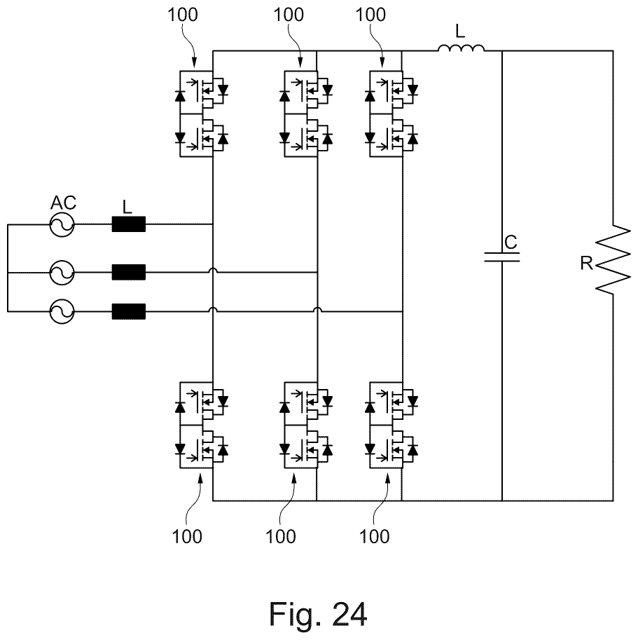

FIG. 24 is an embodiment of a three phase single stage charging topology with a DC load that implements bidirectional switching assemblies.

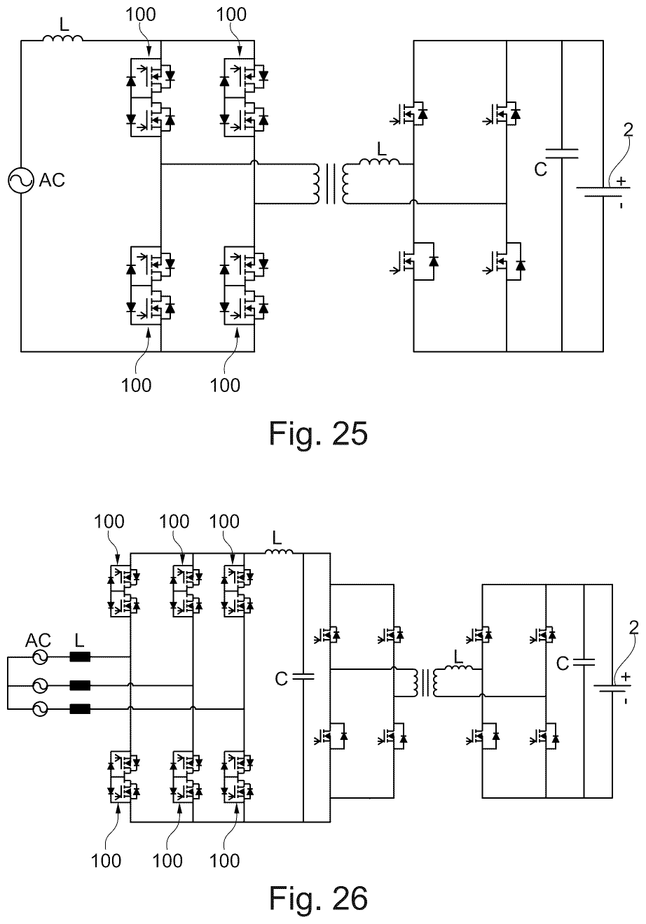

FIG. 25 is an embodiment of an isolated single phase charging circuit for EV applications that implements bidirectional switching assemblies.

FIG. 26 is an embodiment of an isolated three phase charging circuit for EV applications that implements bidirectional switching assemblies.

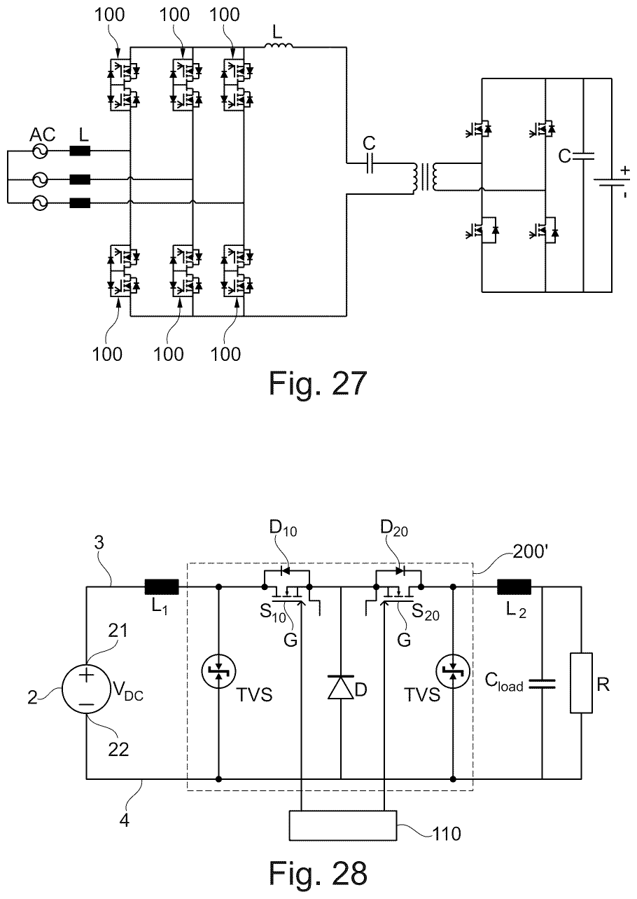

FIG. 27 is an embodiment of an isolated charging circuit for EV applications with LC resonance that implements bidirectional switching assemblies.

FIG. 28 shows a DC power distribution and protection system that implements a solid state power controller with bidirectional switching assemblies not in accordance with the present disclosure.

### DETAILED DESCRIPTION

Before discussing embodiments of the present disclosure with respect to FIGS. 1 to 27, the background of the disclosure is discussed with respect to FIG. 28 to provide for a better understanding of the present disclosure.

FIG. 28 shows a DC power distribution and protection system that includes a solid state power controller 200′, in the following referred to as SSPC. The system includes a DC power source 2 (such as a DC battery) that has a positive terminal 21 and a negative terminal 22. Between the positive terminal 21 and the negative terminal 22 a voltage VDC is present. A positive voltage rail 3 is connected to the positive terminal 21 and a negative voltage rail 4 is connected to the negative terminal 22. The positive voltage rail 3 and the negative voltage rail 4 form a high-voltage bus.

The system further includes a load R, wherein the load R may be formed in a plurality of manners. In examples, the load may be a power converter such as an inverter and/or an electric motor. A capacitive load depicted as C_{load} is arranged in parallel to the load R and extends between the positive voltage rail 3 and the negative voltage rail 4. For example, the capacitive load C_{load} may be formed by DC link capacitors or include such capacitors.

The SSPC 200′ is a bidirectional SSPC and includes a first semiconductor switch S10 with an antiparallel bypass diode D10 and a second semiconductor switch S20 with an antiparallel bypass diode D20, both arranged in the positive voltage rail 3. As the SSPC is bidirectional, it is able to isolate the positive voltage rail 3 in both directions. In other embodiments, the SSPC 200′ additionally includes bidirectional semiconductor switches on the negative voltage rail 4 or includes semiconductor switches on the negative voltage rail 4 only.

The switches S10, S20 may be MOSFET (metal-oxide-semiconductor field-effect transistor), GaN (Gallium Nitride), SiC (Silicon Carbide), or IGBT (Insulated Gate Bipolar Transistor) switches. A further diode D may extend between the positive voltage rail 3 and the negative voltage rail 4. Further, optionally, a transient voltage suppressor diodes TVS may extend between the positive voltage rail 3 and the negative voltage rail 4.

The SSPC 200′ further includes a gate driver 110 that is responsible for controlling the switching of the semiconductor switches S10, S20 and provides the necessary gate signals to the control terminals, i.e., the gates G of semiconductor switches S10, S20. The SSPC 200′ may also include a microcontroller (not shown) for control of the logic and for generating a pulsed signal for the gate driver 110.

In FIG. 28, the semiconductor switches S10, S20 with antiparallel diodes D10, D20 are connected in common source/emitter configuration. The antiparallel diodes D10, D20 give current that flows in the opposite direction a path to flow. The system further includes two inductances L1, L2, one before switch S10 and one behind switch S20, wherein the inductances L1, L2 are configured to limit the rate of rise of current in case of a short-circuit fault.

The semiconductor switches S10, S20 are high-voltage MOSFET or IGBT switches and form a bidirectional switching assembly. One major concern of such bidirectional switching assembly are a high voltage drop, a high power loss, and large footprint requirements.

FIG. 1 shows an embodiment of a bidirectional switching assembly 100 with improved performance compared to the switching assembly implemented in FIG. 28. The bidirectional switching assembly 100 includes a first switching unit S1, a second switching unit S2, and a third switching unit S3. The first switching unit S1 includes a first low-voltage MOSFET T1 and an antiparallel diode D15. The second switching unit S2 includes a second low-voltage MOSFET T2 and an antiparallel diode D16. Sandwiched between the first switching unit S1 and the second switching unit S2 is the third switching unit S3, wherein the third switching unit S3 includes a high-voltage JFET semiconductor switch T3 (e.g., SiC JFET). In another embodiment, T3 is a HEMT semiconductor switch (e.g., GaN HEMT).

The first MOSFET T1 includes a gate G1 that is controlled by a first gate driver 111. The second MOSFET T2 includes a gate G2 that is controlled by a second gate driver 112. The gate drivers 111, 112 may be controlled by a higher level controller. Also, in an alternative embodiment, one gate driver is used to drive both gates G1, G2. The JFET T3 includes a gate G3 that is not controlled through a gate driver, but which is controlled through MOSFETs T1, T2. To this end, the third gate G3 is connected through a first high-voltage diode D1 with an input side IN of the bidirectional switching assembly 100. The third gate G3 is further connected through a high-voltage diode D2 with an output side OUT of the bidirectional switching assembly 100. More particularly, one terminal of diode D1 is connected the gate G3 and the other terminal of D1 is connected to the input side IN of the switching assembly. Similarly, one terminal of diode D2 is connected to gate G3 and in the other terminal of D2 is connected to the output side OUT of the switching assembly. The diodes D1, D2 are high-voltage diodes that prevent the gate G3 to connect into the rail with the source and drain terminals of switches T1, T2, T3. They do not carry large currents and are only used for blocking.

The MOSFETs T1, T2 and the JFET T3 are arranged such that in one direction (in case of current flow from left to right) the JFET T3 and the MOSFET T2 form a cascode, and that in the other direction (in case of current flow from right to left) the JFET T3 and the MOSFET T1 form a cascode. Accordingly, drain/source of the respective switches T1, T3, T2 are connected.

The JFET T3 represents a normally ON high-voltage semiconductor switch, which means that it is able to guide a current if there is no specific voltage applied to its gate G3. On the other hand, the MOSFETs T1, T2 are normally OFF low-voltage semiconductor switches, which means that they only guide current if a specific voltage is applied to its gates G1, G2 by the respective gate driver 111, 112. The depicted circuit functions such that a current may be guided in either direction when the third switching unit S3 is switched on and that a current flow is blocked in either direction when the third switching unit S3 is switched off, wherein the third switching unit S3 is switched on and off through the first and second switching units S1, S2, as discussed in more detail with reference to FIGS. 2A to 2D.

The switching assembly 100 may be realized monolithically or as a power module connecting discrete MOSFET, JFET and diode components in a substrate. The low Voltage MOSFETs T1, T2 are high current capable. They may be configured to have a maximum drain-to-source voltage of 40 Volts and to have a maximum 500 Ampere maximum current through the drain-source channel. The resistance of the drain-source channel in the ON state of the MOSFETs T1, T2 may be in the range of 0.5 mΩ (milliohm). The high-voltage JFET T3 may be configured to block a voltage of at least 1000 V, such as 1200 V or 2400 V.

FIG. 1A depicts a symbol representation of the bidirectional switching assembly of FIG. 1.

According to FIG. 2A, the situation is considered that a current is flowing from point A to point B. For example, point A is connected to a positive DC terminal and point B is connected to a load. If the current is flowing from A to B, the antiparallel diode D15 of the first switching unit S1 will conduct and a current will pass through JFET T3 and then through MOSFET T2 if MOSFET T2 is in ON state. To this end, a turn ON voltage from gate driver 112 of FIG. 1 is applied to the gate G2 of MOSFET T2. During this time, blocking high-voltage diode D1 will be reverse biased, while high-voltage diode D2 will be forward biased, wherein the JFET T3 conduction is based on the voltage drop across MOSFET T2.

In an embodiment, MOSFET T1 is also turned ON, wherein MOSFET T1 will also conduct current and have lower losses.

FIG. 2B shows the situation that the switching unit S2 is switched/turned off (by the gate driver 112 providing a corresponding control signal to the gate G2 of T2). In such case, the voltage drop ΔS_S2 across switching unit S2 will increase. At the same time, a positive voltage is maintained at A. Accordingly, the voltage drop across S2 will increase, thereby the gate voltage at gate G3 of JFET T3 will increase in the negative direction. This leads to JFET T3 becoming fully switched/turned off and JFET T3 starts to block the high voltage ΔV_S3, as indicated in FIG. 2B.

In its blocking state, high-voltage diode D1 prevents the JFET gate G3 to see a large positive voltage applied at A. This allows the JFET T3 to be put into the OFF state from both directions while protecting the JFET gate G3. Once the JFET T3 is turned OFF, the full voltage across the JFET and small voltages across the MOSFET T2 apply. The current flow is completely stopped.

FIG. 2C considers the situation of a reverse current flow, wherein a current is flowing from point B to point A. If the current is flowing from B to A, the antiparallel diode D16 of the second switching unit S2 will conduct and a current will pass through JFET T3 and then through MOSFET T1 if MOSFET T1 is in ON state. To this end, a turn ON voltage from gate driver 111 of FIG. 1 is applied to the gate G1 of MOSFET T1. During this time, blocking high-voltage diode D2 will be reverse biased, while high-voltage diode D1 will be forward biased, wherein the JFET T3 conduction is based on the voltage drop across MOSFET T1.

In an embodiment, MOSFET T2 is also turned ON, wherein MOSFET T2 will also conduct current and have lower losses.

FIG. 2D shows the situation that the switching unit S1 is switched/turned off (by the gate driver 111 providing a corresponding control signal to the gate G1 of T1). In such case, the voltage drop across switching unit S1 will increase. At the same time, a positive voltage is maintained at B. Accordingly, the voltage drop across S1 will increase, thereby the gate voltage at gate G3 of JFET T3 (bias voltage) will increase. This leads to JFET T3 becoming fully switched/turned off and JFET T3 starts to block the high voltage.

In its blocking state, high-voltage diode D2 prevents the JFET gate G3 to see a large positive voltage applied at B. This allows the JFET T3 to be put into the OFF state from both directions while protecting the JFET gate G3. Once the JFET T3 is turned OFF, the full voltage across the JFET and small voltages across MOSFET T1 apply. The current flow is completely stopped.

Both MOSFETs T1, T2 may receive at their gates G1, G2 the same logic pulse irrespective of the voltage or current direction, while this is not necessarily the case. At the same time, both MOSFET gates G1, G2 may be supplied with two different isolated power supplies as they will drive respective drains that are connected to point A or B.

Accordingly, as is clear from FIGS. 2A to 2D, JFET T3 is blocking (switched off) in one direction if MOSFET T2 (and optionally also MOSFET T1) is switched off and JFET T3 is blocking (switched off) in the other direction if MOSFET T1 (and optionally also MOSFET T2) is switched off. When both MOSFET T1 and MOSFET T2 are switched off, JFET T3 blocks current in both directions. At the same time, JFET T3 is guiding current in one direction if T2 is switched on and JFET T3 is guiding current in the other direction if T1 is switched on. For example, by switching T2 off, JFET T3 and the switching assembly 100 are changed from a state in which a current is guided through the switching assembly in one direction to a state in which current flow is blocked. Similarly, by switching T1 off, JFET T3 and the switching assembly 100 are changed from a state in which a current is guided through the switching assembly in the other direction to a state in which current flow is blocked. The switching status of T1 and/or T2 thus defines if the JFET T3 is blocking or not.

FIG. 3 shows an embodiment of a bidirectional switching assembly 100 that is similar to the switching assembly of FIG. 1 except that additionally transient voltage suppressor diodes TVS1, TVS2 are arranged in parallel to the MOSFETs T1, T2 for over voltage protection. Thereby, during the off state, the voltage across the MOSFETs T1, T2 will be low voltage (the TVS voltage) and the full blocking voltage appears across the JFET T3.

FIG. 4 shows an embodiment of a bidirectional switching assembly 100 that is similar to the switching assembly of FIG. 1 except that a JFET T3 with a dual gate a configuration is implemented. Accordingly, JFET T3 includes a first gate G3_1 and a second gate G3_2, wherein both gates are able to control the current flow between drain and source of the JFET. In this embodiment, high-voltage diode D1 is connected with one of its terminals to the first gate D3_1 and high-voltage diode D2 is connected with one of its terminals to the second gate G3_1. The high voltage blocking diodes D1, D2 protect the respective gate voltage. Such embodiment increases the blocking capability of the switch on both directions.

FIG. 5A depicts a further embodiment of a bidirectional switching assembly 100 that includes a first switching unit S1, a second switching unit S2 and a third switching unit S3 sandwiched between the other switching units S1, S2. The main difference with respect to the embodiment of FIG. 1 lies in that the third switching unit S3 includes two JFET semiconductor switches T31, T32 connected in series, thereby increasing the blocking voltage. The first and second switching units S1, S2 are built in the same manner as in FIG. 1.

The two JFETs T31, T32 each include a gate G31, G32, wherein the Gates G31, G32 are connected through high-voltage diode D1 with the input side IN and gates G31, G32 are connected through high-voltage diode D2 with the output OUT. In this respect, the high-voltage diodes D1, D2 may include several high-voltage diodes arranged in series, such as diodes D11, D12 and D21, D22 as shown in FIG. 5A. The diodes D1, D2 serve the same function as in FIG. 1, namely, the blocking of high voltage.

The switching assembly of FIG. 5A further includes a balancing circuit to consider the presence of two JFETs T31, T32, wherein the balancing circuit provides for equal sharing of the blocking voltage between the two JFETs and also makes sure that both JFETs are switched on and off at the same time. The balancing circuit includes two avalanche diodes D3, D4 connected to back to back, wherein the gates G31, G32 of JFETs T31, T32 are connected through the avalanche diodes D3, D4. As the two avalanche diodes D3, D4 are connected back to back, one will be conducting and other will be blocking based on the current directions.

The balancing circuit further includes low-voltage diodes D5, D6. Diode D5 has a terminal connected to a point between the first and third semiconductor switches S1, S3 and a terminal connected to the gate G31 of T31. Diode D6 has a terminal connected to a point between the third and second semiconductor switches S3, S2 and a terminal connected to the gate G32 of T32. The diodes D5 and D6 are low voltage (less than 50V) and low current rated. Further, a plurality of resistors R1 to R4 are provided. The avalanche diodes D3, D4, the additional diodes D5, D6 and the resistors R1 to R4 are used for the balancing voltage across the JFETs T31, T32.

The switching assembly 100 may be realized monolithically or as a power module connecting discrete MOSFET, JFET, and diode components in a substrate. The low Voltage MOSFETs T1, T2 are high current capable. They may be configured to have a maximum drain-to-source voltage of 40 Volts and to have a 500 Ampere maximum current through the drain-source channel. The resistance of the drain-source channel in the ON state of the MOSFETs T1, T2 may be in the range of 0.5 mΩ (milliohm). The high-voltage JFETs T31, T32 may be configured to block a voltage of 1200 V, such that they put together a block a voltage of 2400 V. They may have a maximum current through the drain-source channel of 120 Ampere.

In case of higher current requirements, several JFETs and also several MOSFETs may be connected in parallel. This also applies to the embodiment of FIG. 1.

The JFET semiconductor switches T31, T32 may be SiC JFETs. In another embodiment, T31, T32 are HEMT semiconductor switches such as GaN HEMT.

FIG. 5B shows a switching assembly 100 that is modified with respect to the switching assembly of FIG. 5A in that additionally a slew rate control is implemented by adding a resistor R5 between the avalanche diodes D3, D4 and by having a capacitor C1 between diodes D1, D2, wherein the capacitor C1 and the resistor R5 form a filtering circuit that limits the rate of change of the gate signal. The capacitor C1 may be in pF range and the resistor R5 in the kΩ range, wherein the current flowing through the capacitor C1 and the resistor R5 will be very small.

The function of the switching assemblies of FIGS. 5A, 5B are discussed in more detail with reference to FIGS. 6A to 6D.

According to FIG. 6A, the situation is considered that a current is flowing from point A to point B. For example, point A is connected to a positive DC terminal and point B is connected to a load. If the current is flowing from A to B, the antiparallel diode D15 of the first switching unit S1 will conduct and a current will pass through JFETs T31, T32 and then through MOSFET T2 if MOSFET T2 is in ON state. To this end, a turn ON voltage from a gate driver is applied to the gate G2 of MOSFET T2. During this time, blocking high-voltage diode D1 will be reverse biased, while high-voltage diode D2 will be forward biased, wherein the JFET T31, T32 conduction is based on the voltage drop across MOSFET T2.

In an embodiment, MOSFET T1 is also turned ON, wherein MOSFET T1 will also conduct current and have lower losses.

FIG. 6B shows the situation that the switching unit S2 is switched/turned off (by the gate driver providing a corresponding control signal to the gate G2 of T2). In such case, the voltage drop across switching unit S2 will increase. Thereby the bias gate voltage at gates G31, G32 of JFETs T31, T32 will increase in the negative direction. This leads to JFETs T31, T32 becoming fully switched/turned off and JFETs T31, T32 starting to block the high voltage.

In its blocking state, high-voltage diode D1 prevents the gates G31, G32 to see a large positive voltage applied at A. This allows the JFETs to be put into the OFF state from both directions while protecting the JFETs gates. Once the JFETs T31, T32 are turned OFF, the full voltage across the JFETs T31, T32 and small voltages across the MOSFET T2 apply. The current flow is completely stopped.

The avalanche diodes D3, D4 balance the voltage across the JFETs T31, T32. In case of FIG. 5B with a resistance R5 and a capacitor C1 provide control of the slew rate.

FIG. 6C considers the situation of a reverse current flow, wherein a current is flowing from point B to point A. If the current is flowing from B to A, the antiparallel diode D16 of the second switching unit S2 will conduct and a current will pass through JFETs T32, T31 and then through MOSFET T1 if MOSFET T1 is in ON state. To this end, a turn ON voltage from a gate driver is applied to the gate G1 of MOSFET T1. During this time, blocking high-voltage diode D2 will be reverse biased, while high-voltage diode D1 will be forward biased, wherein the JFETs T31, T32 conduction is based on the voltage drop across MOSFET T1.

FIG. 6D shows the situation that the switching unit S1 is switched/turned off (by a gate driver providing a corresponding control signal to the gate G1 of T1). In such case, the voltage drop across switching unit S1 will increase. At the same time, a positive voltage is maintained at B. Accordingly, the voltage drop across S1 will increase, thereby the gate voltage at gates G31, G32 of JFETs T31, 32 (bias voltage) will increase. This leads to JFETs T31, T32 becoming fully switched/turned off and JFETs T31, T32 starting to block the high voltage.

The same logical pulse may be provided to gates G1, G2 of MOSFETs T1, T2 irrespective of the voltage or current direction.

FIG. 7 shows an embodiment of a bidirectional switching assembly 100 that is similar to the switching assembly of FIG. 5B except that additionally transient voltage suppressor diodes TVS1, TVS2 are arranged in parallel to the MOSFETs T1, T2 for over voltage protection. Thereby, during the off state, the voltage across the MOSFETs T1, T2 will be low voltage (the TVS voltage) and the full blocking voltage appears across the JFETs T31, T32.

FIG. 8 shows an embodiment of a bidirectional switching assembly 100 that is similar to the switching assembly of FIG. 5B except that the cascoded JFETs T31, T32 are connected back-to-back in common drain configuration, as indicated by the position of the gate arrow in JFETs T31, T32. In such a configuration, the requirement of low-voltage MOSFETs may be eliminated by using the MOSFETs in the cascoded JFET. Thereby, it is possible to further reduce the footprint and loss in the system.

FIG. 9 shows an embodiment of a bidirectional switching assembly 100 that is similar to the switching assembly of FIG. 5B except that JFETs T31, T32 with a dual gate configuration are implemented. Accordingly, JFET T31 includes a first gate G31_1 and a second gate G31_2, and JFET T32 includes a first gate G32_1 and a second gate G32_2. Both gates are able to control the current flow between drain and source of the respective JFET. In this embodiment, high-voltage diode D1 is connected with one of its terminals to the gates G31_1, G32_1. High Voltage diode D2 is connected with one of its terminals to the gates G31_2, G32_2. The high voltage blocking diodes D1, D2 protect the respective gate voltage. Additional diodes D7, D8 are provided between G31_1, G32_1 and G31_2, G32_2, respectively. The embodiment of FIG. 9 increases the blocking capability of the switching assembly on both directions.

FIG. 10 is an example embodiment of a bidirectional switching assembly in which the third switching unit S3 includes four JFETs (or HEMTs) arranged in series between the first switching unit S1 and the second switching unit S3. The third switching unit S3 thus includes four JFETs T31-T34. The gates of two respective JFET are connected in each case through two avalanche diodes connected back-to-back, similar as in FIGS. 5A, 5B.

In other embodiments, the bidirectional switching assembly 100 may include a third switching unit S3 with another number of JFETs or HEMTs, such as three, five, or six.

FIGS. 11A to 11E regard different embodiments of a JPEG semiconductor switch T3. In certain examples, a JFET's source and drain terminals are identical, and the doping of carriers is nearly equal. However, conventional JFETs struggle to fully block voltage in both directions, especially in high voltage applications. In high voltage JFETs, the reverse blocking voltage (V_{SD}) is lower than the forward blocking voltage (V_{DS}) due to the proximity of the gate terminal to the source. To address these such challenges, the gate terminal of the JFET is shifted to the middle of the structure, as is illustrated in FIGS. 11A to 11E. FIG. 11A depicts the conventional JFET structure, while FIGS. 11B, 11C and 11D illustrate the improved structure designed to effectively block rated voltage on both sides in different modifications. As shown in the Figures, the JPEG T3 includes a drift region 30 that is arranged between a source terminal SR3 and a drain terminal DR3 of the switch T3. The gate terminal G3 is arranged in the middle of the drift region 30, at even space to the source terminal SR3 and the drain terminal DR3.

In FIG. 11D, the gate G3 forms two sides (or the gate may be made as circle type) to get the effective blocking features.

FIG. 11E shows a dual gate topology JFET that may be used for blocking in both directions. JFET T3 includes first and second gate terminals G3_1, G3_2 that are arranged symmetrically with respect to the source terminal SR3 and the drain terminal DR3. Gate terminal G3_1 is located closer to the source terminal SR3. Gate terminal G3_2 is located closer to the drain terminal DR3.

Modifying the structure as indicated in FIGS. 11B to 11E may impact the switching loss of the system, but the proposed topology is recommended at least for Solid State Power Controllers (SSPCs), where switching loss is not a critical concern for the system.

The bidirectional switching assembly may be implemented in any device that requires bidirectional switching. In embodiments, the bidirectional switching assembly may be implemented in a solid state power controller (SSPC), a matrix converter, a T-Type converter, a Vienna rectifier, or a battery charging circuit.

FIGS. 12 to 27 provide examples of how the bidirectional switching assembly may be implemented in a circuit/system, without these examples limiting the application of the switching assembly.

FIG. 12 depicts a power system that is similar to the power system of FIG. 28. The power system includes a power bus with a positive voltage rail 3 connected to the positive terminal of a DC power source 2 and with a negative voltage rail 4 connected to the negative terminal of the DC power source 2. The power bus 3, 4 serves to connect a load R₀ to the power source 2. A load capacitor C₀ is arranged in parallel to the load R₀. Further, inductors L1, L2 may be provided. In this respect, reference is made to the description of FIG. 28.

An SSPC 200 is arranged in the positive voltage rail 3. The SSPC 200 includes a bidirectional switching assembly 100 that is constructed in accordance with the embodiment of FIG. 1.

The SSPC 200 also includes two gate drivers 111, 112 for the low-voltage MOSFETs T1, T2. The gate drivers 111, 112 are depicted schematically only. In another embodiment, there may be provided a single gate driver for the two MOSFETs S2, S2. The SSPC 200 may further include a microcontroller (not shown) for logic control.

Further, a controller 5 is provided, which is depicted schematically. The controller 5 is configured to receive information about the status of the circuit and the occurrence of a fault condition through input lines 51. Such information may be provided from the gate drivers 111, 112 or from sensor elements associated with the individual switches or other elements (such as thermal sensor or current sensor). For example, if a switch or other element is short-circuited, an error signal is received by controller 5 through input lines 51.

In case a fault condition is detected, the controller 5 is configured to control the SSPC 200 to break a current in the power system. To this end, control signals are sent through output lines 52 to the gate drivers 111, 112, wherein the gate drivers 111, 112 provide control signals to the gates G1, G2 such that the MOSFETs T1, T2 and thus the first and second switching units S1, S2 are switched off, this causing switching off of the high-voltage JFET ST in the manner discussed above.

The controller 5 may include a processor for executing instructions and a memory that is coupled to the processor and in which instructions are stored. When the instructions are executed by the processor, the instructions cause the processor to perform the functions of receiving information about semiconductor switches and other elements in providing control signals to the gate drives 111, 112. The controller 5 may be a separate unit or may be integrated into a gate driver or may be integrated into a microcontroller of the SSPC 200. Also, the controller 5 may communicate with other control devices of the system.

FIG. 13 shows an embodiment of a power system that is similar to the power system of FIG. 12 except that the SSPC includes a bidirectional switching unit 100 in accordance with the dual gate embodiment of FIG. 4.

FIG. 14 shows an embodiment of a power system that is similar to the power system of FIG. 12 except that the SSPC includes a bidirectional switching unit 100 in accordance with the embodiment of FIG. 1 both in the positive voltage rail 3 and the negative voltage rail 4.

FIG. 15 shows an embodiment of a power system that is similar to the power system of FIG. 12 except that the SSPC includes a bidirectional switching unit 100 in accordance with the dual gate embodiment of FIG. 4 both in the positive voltage rail 3 and the negative voltage rail 4.

FIG. 16 shows an embodiment of a power system that is similar to the power system of FIG. 12 except that the SSPC includes a bidirectional switching unit 100 in accordance with the embodiment of FIG. 5B.

FIG. 17 shows an embodiment of a power system that is similar to the power system of FIG. 12 except that the SSPC includes a bidirectional switching unit 100 in accordance with the embodiment of FIG. 9.

FIG. 18 shows an embodiment of a power system that is similar to the power system of FIG. 12 except that the SSPC includes a bidirectional switching unit 100 in accordance with the embodiment of FIG. 5B both in the positive voltage rail 3 and the negative voltage rail 4.

FIG. 19 shows an embodiment of a power system that is similar to the power system of FIG. 12 except that the SSPC includes a bidirectional switching unit 100 in accordance with the dual gate embodiment of FIG. 9 both in the positive voltage rail 3 and the negative voltage rail 4.

A further application of bidirectional switching assemblies are matrix converters. A matrix converter is a power converter that achieves direct AC/AC conversion without an intermediate energy storage, as well known to the skilled person. They are widely used in electrical distribution systems.

An example matrix converter that implements the present disclosure is depicted in FIG. 20. The matrix converter 300 includes an AC input side 310 with an input filter, an AC output side 330 with an output filter, and an array 320 of bidirectional switching assemblies 100 arranged in between. The bidirectional switching assemblies 100 are of the kind discussed with respect to FIGS. 1 to 11, and any of the embodiments of FIGS. 1 to 11 may be implemented. The bidirectional switching assembly 100 are controlled to transfer power from each phase to a respective other phase using similar modulation techniques as known matrix converters.

With such matrix converters, the number of high-voltage switches is reduced compared to conventional matrix converters, and the use of the matrix converters becomes significantly more attractive.

A further application of bidirectional switching assemblies are T type converters, as depicted in FIG. 21. T-type converters are widely used for power factor correction and high-power application in a distribution system. A T-type converter uses bidirectional switches in a neutral Midpoint M of DC-Link capacitors as shown in the FIG. 21. These bidirectional switches may be implemented by bidirectional switching assemblies, such as described with respect to FIGS. 1 to 11.

In a similar manner, bidirectional switching assemblies may be implemented in Vienna rectifiers that combine a three-phase diode bridge with an integrated boost converter. In a Vienna rectifier, a midpoint M of DC-Link capacitors is connected through bidirectional switching assemblies 100, such as described with respect to FIGS. 1 to 11.

A still further application of bidirectional switching assemblies are battery charging circuits for electro vehicle (EV) applications. FIG. 23 shows a charging circuit that implements a bidirectional switch based converter. Bidirectional switching assemblies 100 are implemented in a three-phase single stage charging topology that charges a battery 2. Thereby, the loss and the footprint of the converter may be reduced. Alternatively, as shown in FIG. 24, the charging topology is used for a DC load R.

A still further application of bidirectional switching assemblies are isolated charging circuits, as depicted in FIG. 25, wherein bidirectional switching assemblies are implemented instead of conventional bidirectional circuits. FIG. 26 depicts a three-phase charging circuit for EV applications. FIG. 27 depicts a three-phase charging circuit with LC resonance. In each of these a charging circuits, bidirectional switching assemblies 100 are implemented, such as described with respect to FIGS. 1 to 11.

It should be understood that the above description is intended for illustrative purposes only and is not intended to limit the scope of the present disclosure in any way. Also, those skilled in the art will appreciate that other aspects of the disclosure may be obtained from a study of the drawings, the disclosure and the appended claims. All methods described herein may be performed in any suitable order unless otherwise indicated herein or otherwise clearly contradicted by context. Various features of the various embodiments disclosed herein may be combined in different combinations to create new embodiments within the scope of the present disclosure. In particular, the disclosure extends to and includes all combinations and sub-combinations of one or more features described herein. Any ranges given herein include any and all specific values within the range and any and all sub-ranges within the given range.

1. A bidirectional switching assembly comprising:
a first switching unit having a first low voltage metal-oxide-semiconductor field-effect transistor (MOSFET), wherein the first low voltage MOSFET comprises a first gate;
a second switching unit having a second low voltage MOSFET, wherein the second low voltage MOSFET comprises a second gate; and
a third switching unit having a normally ON high voltage semiconductor switch, wherein the normally ON high voltage semiconductor switch comprises a third gate, and wherein the third gate is connected through high-voltage diodes with an input side and with an output side of the bidirectional switching assembly,
wherein the first switching unit, the second switching unit, and the third switching unit are arranged in series with the third switching unit positioned between the first switching unit and the second switching unit,
wherein, in a first direction, the second switching unit and the third switching unit form a first cascode,
wherein, in a second, opposite direction, the first switching unit and the third switching unit form a second cascode,
wherein the bidirectional switching assembly is configured to conduct a current in either the first direction or the second direction when the third switching unit is switched on,
wherein the bidirectional switching assembly is configured to block a current in either the first direction or the second direction when the third switching unit is switched off, and
wherein the third switching unit is switched on and off by switching on and off at least one unit of the first switching unit and the second switching unit.

2. The bidirectional switching assembly of claim 1, wherein the high-voltage diodes comprise a first high-voltage diode connected at one terminal to the third gate and connected at another terminal to the input side of the bidirectional switching assembly, and a second high-voltage diode connected at one terminal to the third gate and connected at another terminal to the output side of the bidirectional switching assembly.

3. The bidirectional switching assembly of claim 1, wherein the first switching unit and the second switching unit each comprise an antiparallel diode arranged antiparallel to the first low voltage MOSFET and the second low voltage MOSFET, respectively.

4. The bidirectional switching assembly of claim 1, wherein the first switching unit and the second switching unit each comprise a bidirectional transient voltage suppressor diode arranged in parallel to the first low voltage MOSFET and the second low voltage MOSFET, respectively.

5. The bidirectional switching assembly of claim 1, wherein the first low voltage MOSFET and the second low voltage MOSFET are controlled with a same logic signal.

6. The bidirectional switching assembly of claim 1, wherein the first low voltage MOSFET and the second low voltage MOSFET are driven by independent gate drivers.

7. The bidirectional switching assembly of claim 1, wherein the bidirectional switching assembly is configured to conduct a current in the first direction when at least the second switching unit and the third switching unit are switched on, and
wherein the bidirectional switching assembly is further configured to conduct a current in the second direction when at least the first switching unit and the third switching unit are switched on.

8. The bidirectional switching assembly of claim 7, wherein the bidirectional switching assembly is configured to change from a first state in which a current is guided in the first direction to a second state in which a current in either direction is blocked,
wherein, in the first state, the second low voltage MOSFET is configured to be switched on, and
wherein, in the second state, the second low voltage MOSFET is configured to be switched off.

9. The bidirectional switching assembly of claim 1, wherein the first low voltage MOSFET and the second low voltage MOSFET are configured to have a maximum drain-to-source voltage of 40 Volts and/or to have a maximum current of 500 Ampere through a drain-source channel.

10. The bidirectional switching assembly of claim 1, wherein the normally ON high voltage semiconductor switch comprises a dual gate configuration with a first third gate and a second third gate,
wherein the first third gate is connected through a high-voltage diode with the input side of the bidirectional switching assembly, and
wherein the second third gate is connected through a high-voltage diode with the output side of the bidirectional switching assembly.

11. The bidirectional switching assembly of claim 1, wherein the third semiconductor switch comprises first and second normally ON high voltage semiconductor switches arranged in series and both positioned between the first semiconductor switch and the second semiconductor switch, and
wherein each gate of the first and second normally ON high voltage semiconductor switches is connected through at least one high-voltage diode with the input side and with the output side of the bidirectional switching assembly.

12. The bidirectional switching assembly of claim 11, further comprising:
a balancing circuit configured to balance a voltage across the first and second normally ON high voltage semiconductor switches,
wherein the balancing circuit comprises two avalanche diodes connecting the gates of the first and second normally ON high voltage semiconductor switches.

13. The bidirectional switching assembly of claim 12, wherein the balancing circuit further comprises:
a first low-voltage diode having a terminal connected to a point between the first semiconductor switch and the third semiconductor switch and a terminal connected to the gate of the first normally ON high voltage semiconductor switch; and
a second low-voltage diode having a terminal connected to a point between the second semiconductor switch and the third semiconductor switch and a terminal connected to the gate of the second normally ON high voltage semiconductor switch.

14. The bidirectional switching assembly of claim 1, wherein the normally ON high voltage semiconductor switch comprises a drift region arranged between a source terminal and a drain terminal of the normally ON high voltage semiconductor switch, and
wherein a gate terminal of the normally ON high voltage semiconductor switch is arranged in a middle of the drift region, evenly spaced to the source terminal and the drain terminal.

15. The bidirectional switching assembly of claim 14, wherein the normally ON high voltage semiconductor switch comprises first and second gate terminals, and
wherein the first and second gate terminals are arranged symmetrically with respect to the source terminal and the drain terminal.

16. The bidirectional switching assembly of claim 1, wherein the normally ON high voltage semiconductor switch is a JFET or HEMT semiconductor switch.

17. The bidirectional switching assembly of claim 1, wherein the bidirectional switching assembly is an element of a solid state power controller, a matrix converter, a T-Type converter, a Vienna rectifier, or a battery charging circuit.

18. A power system comprising:
a power bus comprising a positive voltage rail and a negative voltage rail, wherein the power bus is configured to connect a power source with a load; and
a bidirectional solid state power controller arranged in at least one of the positive voltage rail and the negative voltage rail,
wherein the bidirectional solid state power controller comprises a bidirectional switching assembly having:
a first switching unit having a first low voltage metal-oxide-semiconductor field-effect transistor (MOSFET), wherein the first low voltage MOSFET comprises a first gate;
a second switching unit having a second low voltage MOSFET, wherein the second low voltage MOSFET comprises a second gate; and
a third switching unit having a normally ON high voltage semiconductor switch, wherein the normally ON high voltage semiconductor switch comprises a third gate, and wherein the third gate is connected through high-voltage diodes with an input side and with an output side of the bidirectional switching assembly,
wherein the first switching unit, the second switching unit, and the third switching unit are arranged in series with the third switching unit positioned between the first switching unit and the second switching unit,
wherein, in a first direction, the second switching unit and the third switching unit form a first cascode,
wherein, in a second, opposite direction, the first switching unit and the third switching unit form a second cascode,
wherein the bidirectional switching assembly is configured to conduct a current in either the first direction or the second direction when the third switching unit is switched on,
wherein the bidirectional switching assembly is configured to block a current in either the first direction or the second direction when the third switching unit is switched off, and
wherein the third switching unit is switched on and off by switching on and off at least one unit of the first switching unit and the second switching unit.

19. The power system of claim 18, further comprising:
a controller configured to receive information or determine that there is a fault,
wherein, when the fault is determined or the information is received by the controller, the controller is further configured to control the first switching unit and the second switching unit of the bidirectional switching assembly such that the first switching unit and the second switching unit are switched off.

20. A matrix converter comprising:
an AC input side;
an AC output side; and
an array of bidirectional switching assemblies arranged between the AC input side and the AC output side,
wherein each bidirectional switching assembly of the array of bidirectional switching assemblies comprises:
a first switching unit having a first low voltage metal-oxide-semiconductor field-effect transistor (MOSFET), wherein the first low voltage MOSFET comprises a first gate;
a second switching unit having a second low voltage MOSFET, wherein the second low voltage MOSFET comprises a second gate; and
a third switching unit having a normally ON high voltage semiconductor switch, wherein the normally ON high voltage semiconductor switch comprises a third gate, and wherein the third gate is connected through high-voltage diodes with an input side and with an output side of the bidirectional switching assembly,
wherein the first switching unit, the second switching unit, and the third switching unit are arranged in series with the third switching unit positioned between the first switching unit and the second switching unit,
wherein, in a first direction, the second switching unit and the third switching unit form a first cascode,
wherein, in a second, opposite direction, the first switching unit and the third switching unit form a second cascode,
wherein the bidirectional switching assembly is configured to conduct a current in either the first direction or the second direction when the third switching unit is switched on,
wherein the bidirectional switching assembly is configured to block a current in either the first direction or the second direction when the third switching unit is switched off, and
wherein the third switching unit is switched on and off by switching on and off at least one unit of the first switching unit and the second switching unit.
